(19) United States
(12) Patent Application Publication
(10) Pub. No.: US 2018/0130859 A1
(43) Pub. Date: May 10, 2018

(54) DISPLAY DEVICE

(71) Applicant: Japan Display Inc., Minato-ku (JP)

(72) Inventor: Masumi NISHIMURA, Minato-ku (JP)

(73) Assignee: Japan Display Inc., Minato-ku (JP)

(21) Appl. No.: 15/784,933

(22) Filed: Oct. 16, 2017

(30) Foreign Application Priority Data
Nov. 8, 2016 (JP) 2016-218076

(51) Int. Cl. H01L 27/32; H01L 51/52; H01L 51/00

(52) U.S. Cl. CPC H01L 27/3248; H01L 51/5203; H01L 27/3276; H01L 51/5237; H01L 51/0097

(57) ABSTRACT

The purpose of the present invention is to realize a reliable bendable organic EL display device with high reliability. The structure of the invention is as follows. An organic EL display device comprising: a lower electrode, an upper electrode, an organic layer that is sandwiched by the lower electrode and the upper electrode, a thin film transistor connecting with the lower electrode, a first inorganic protective film covering the organic layer; wherein a common voltage is supplied through a first elastic conductive film, a drain electrode of the thin film transistor is connected with a power line through a second elastic conductive film.

### CLAIM OF PRIORITY

The present application claims priority from Japanese Patent Application JP 2016-218076 filed on Nov. 8, 2016, the content of which is hereby incorporated by reference into this application.

### BACKGROUND OF THE INVENTION

### (1) Field of the Invention

The present invention relates to a flexible display device that the substrate is bendable.

### (2) Description of the Related Art

An organic EL display device and a liquid crystal display device can be flexibly bent by making those displays thin. An organic EL display device can be more flexible than a liquid crystal display device because an organic EL display device doesn't need a backlight.

Patent document 1 (Japanese patent laid open Hei 5-107531) discloses to form one of the substrate by an organic substance to avoid deviation between pixels of the lower substrate and the pixels of the upper substrate because of the difference in radius of curvature between the lower substrate and the upper substrate when the ferroelectric liquid crystal display panel is bent.

Patent document 2 (Japanese patent laid open 2014-151617) discloses to form an adhesive layer between the elastic substrate and the elastic wirings to avoid peeling off of the elastic wirings from the elastic substrate. Patent document 3 (Japanese patent laid open 2014-165426) discloses to embed the elastic wirings in the elastic substrate.

### SUMMARY OF THE INVENTION

An organic EL display device and a liquid crystal display device can be flexibly bent by making substrates by flexible organic substance. Specifically, an organic EL display device can be more flexible because it doesn't need a backlight.

The organic EL display device has TFTs (Thin Film Transistors), electrodes, organic EL layers including a light emitting layer, insulating films or protecting films on the substrate (herein after TFT substrate). Some of those are formed by inorganic substance like SiO or SiN. (SiOx is represented by SiO; SiNx is represented by SiN in the specification.) There is a chance that those inorganic substances are broken or develop cracks when the displays are bent since those inorganic films are hard. Metal wirings, which are formed by thin films, are formed on the TFT substrate; those wirings tend to get disconnections when the display device is bent.

The purpose of the present invention is to prevent those inorganic insulating layer and inorganic protective layer from being broken or to prevent those wirings from getting disconnections when the display is bent; thus, to realize reliable flexible display devices.

The present invention can solve the above problems; concrete measures are as follows:

(1) An organic EL display device comprising: a lower electrode, an upper electrode, an organic layer that is sandwiched by the lower electrode and the upper electrode, a thin film transistor connecting with the lower electrode, a first inorganic protective film covering the organic layer; wherein a common voltage is supplied through a first elastic conductive film, a drain electrode of the thin film transistor is connected with a power line through a second elastic conductive film.

(2) An organic EL display device comprising; scanning lines extend in a first direction and arranged in a second direction, video signal lines and power lines extend in parallel in a second direction and arranged in a first direction, a pixel is formed in an area surrounded by the scanning line, the video signal line and the power line; an organic layer formed between a lower electrode and an upper electrode, a first transistor that drives the organic layer, a second transistor that connects with a gate of the first transistor are formed in the pixel; wherein the organic layer is covered by an island shaped first inorganic protective film, a gate of the second transistor connects with the scanning line, a drain of the second transistor connects with the video signal line, a drain of the first transistor connects with the power line, a source of the first transistor connects with the lower electrode, the upper electrode connects with a common voltage supply line, the scanning line is formed by a first elastic conductive film, the video signal line is formed by a second elastic conductive film, the power line is formed by a third elastic conductive film, the common voltage supply line is formed by a fourth elastic conductive film.

### BRIEF DESCRIPTION OF THE DRAWINGS

FIG. 1 is a cross sectional view according to the present invention;

FIG. 2 is an equivalent circuit of the pixels;

FIG. 3 is a plan view of pixels according to the present invention;

FIG. 4 is cross sectional view along the line A-A of FIG. 3;

FIG. 5 is a cross sectional view that the polarizing plate is adhered to the organic EL device;

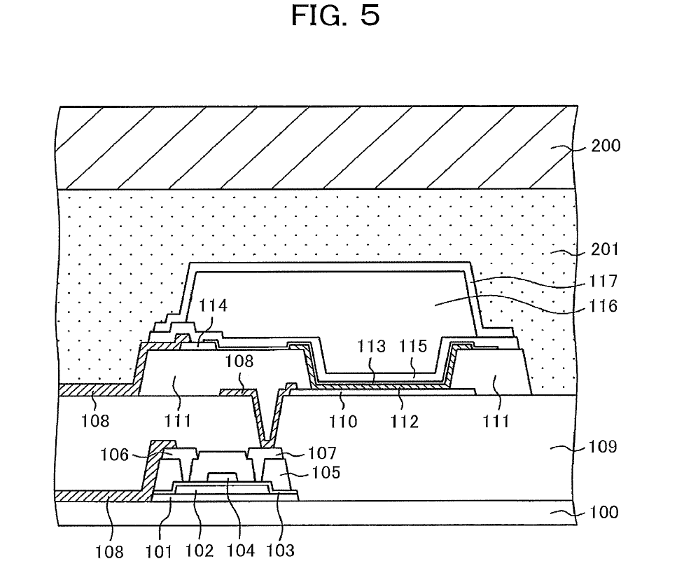

FIG. 6 is a cross sectional view of the pixel of another example of the present invention;

FIG. 7 is a cross sectional view of the pixel that does not use the present invention.

### DETAILED DESCRIPTION OF THE PREFERRED EMBODIMENTS

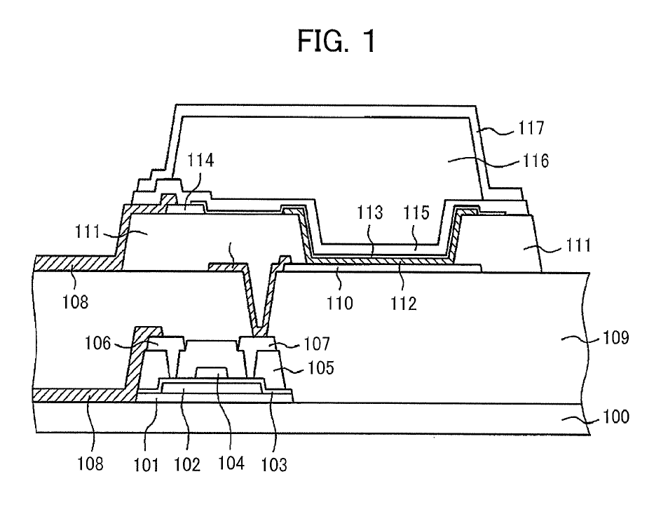

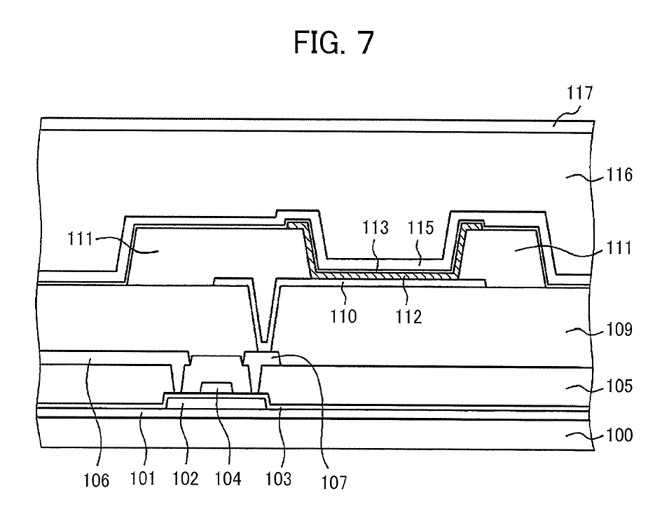

Before explaining the structure of the present invention, a comparative example of the organic EL display device that doesn't use the present invention is explained. FIG. 7 is a cross sectional view of the organic EL display device as a comparative example. Since detailed structure will be explained in FIG. 1, only outlines of the structures are explained here. In FIG. 7, the undercoat 101 by SiO or SiN is formed on the TFT substrate that is formed by resin. The semiconductor layer 102, the gate insulating film 103, which covers the semiconductor layer 102, are formed on the undercoat 101.

The gate electrode 104 is formed on the gate insulating film 103; the interlayer insulating film 105 is formed by e.g. SiN on the gate electrode 104. The through holes are formed in the interlayer insulating film 106 and the gate insulating film 103 to connect the semiconductor layer 102 with the drain electrode 106 or the source electrode 107, which are formed by metal or alloy. The organic passivation film 108 is formed on the drain electrode 106 or the source electrode 107. The lower electrode 110 is formed on the organic passivation film 109; the lower electrode 110 works also as a reflecting electrode. The bank 111 is formed to cover the periphery of the lower electrode 110.

The organic EL layer 112 is formed in a hole of the bank 111; the upper electrode 113 is formed on the organic EL layer 111. The upper electrode 113, which is formed by an oxide conductor film, a metal film, or an alloy film, is formed all over the display area, in other words, the upper electrode is formed in common on plural pixels. The protective layer is formed on the upper electrode 113. The protective layer comprises: a first inorganic protective film 115 formed by e.g. SiN, an organic protective film 116 formed by e.g. acrylic and a second inorganic protective film 117 formed by e.g. SiN.

In FIG. 7, the undercoat 101, the gate insulating film 103, the interlayer insulating film 105, the first inorganic protective film 115, the second inorganic protective film 117 are formed by e.g. SiO or SiN, which are hard and formed in a large area. Therefore, when the display is bent, those layers tend to be broken or to develop cracks; consequently, they will not be able to work properly as an insulating layer or a protective layer.

In addition, the drain electrode 106 and the source electrode 107 (formed simultaneously with the video signal line), the gate electrode 204 (formed simultaneously with the gate signal line) are formed by metal or alloy, which are thin films of a thickness of about 200 nm and the widths are narrow. Therefore, the disconnections in those electrodes tend to occur.

Besides, the upper electrode is a thin layer and formed in all over the display area continuously. Therefore, there exists a chance that cracks are developed in the upper electrode 113 when the display is bent

As described above, the structure that doesn't use the present invention has a problem of reliability when it is bent. The present invention solves this problem. The preset invention is explained by the embodiments in detail.

### First Embodiment

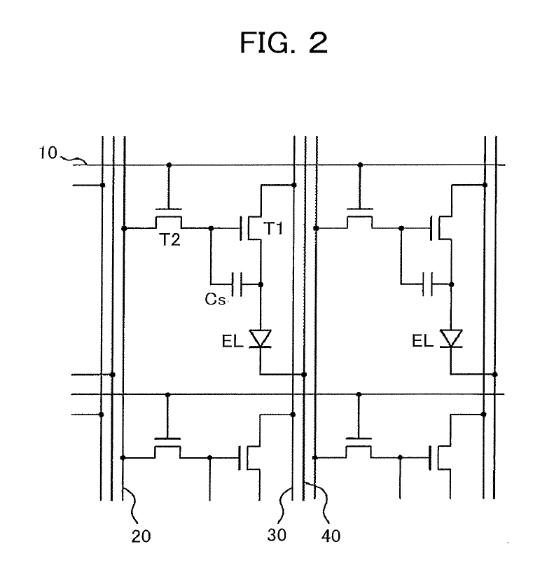

FIG. 1 is a cross sectional view of the organic EL display device according to the present invention. FIG. 1 is a cross sectional view of the driving TFT (T1) and the organic EL element (EL) in the pixel, which is explained in FIG. 2. Herein after, if it is not specifically noted, the TFT means the driving TFT (T1). In FIG. 1, the TFT substrate 100 is formed by glass or resin. Glass, if the thickness is 0.2 mm or less, can be flexibly bent. On the other hand, if the TFT substrate is formed by resin, the display device becomes more flexible.

Polyimide is specifically suitable for the substrate because of its heat resistance and its mechanical strength. Since polyimide can be made as thin as 5-20 μm, a very thin display device can be realized. A manufacturing method of the TFT substrate 100 of polyimide is as follows:

At the outset, polyamic acid, which is material of the polyimide, is coated on the glass substrate, then the polyamic acid is imidized; consequently the TFT substrate 100 of approximately 10-20 μm in thickness is formed. After that, the TFTs, the organic passivation film, insulating layers, wirings, protective layers are formed on the TFT substrate 100. After that, a laser is irradiated at the interface of the glass substrate and the polyimide film (TFT substrate), then, the glass substrate is removed from the TFT substrate.

Back to FIG. 1, the undercoat 101 is formed on the TFT substrate 100. However, unlike a conventional structure, the undercoat is formed island like at a portion where the TFT is formed. The undercoat is formed by CVD on all over the TFT substrate, then, is patterned in island like by photo lithography. The function of the undercoat is to block the impurity from the glass substrate or the resin substrate; thus, to protect the semiconductor 102 of the TFT from being contaminated by the impurity.

The undercoat 101 is generally formed by a laminated film of a SiN film and a SiO film; both of SiN and SiO are hard materials. Thus, when the display device is bent, the undercoat 101 develops e.g. cracks, and consequently is destroyed. In this invention, however, the undercoat 101 is formed in a limited area where TFT is formed; thus, stress to the undercoat is limited in an extent that the undercoat 101 is not broken.

The semiconductor layer 102 is formed on the undercoat 101. The semiconductor layer 102 is formed by the LTPS (Low Temperature Poly-Si). Manufacturing process for the LTPS is as that: the a-Si is formed on all over the substrate by CVD, then, the a-Si is transformed to the Poly-Si by irradiating excimer laser on it; then, the Poly-Si is patterned by photo lithography.

After that, the gate insulating film 103 is formed on the semiconductor layer 102. The gate insulating film 103 is SiO formed by CVD using TEOS (Tetraethyl orthosilicate) as material. The gate insulating film is also formed on all over the substrate first, then, it is patterned by photo lithography.

The gate electrode 104 is formed by a metal or an alloy on the gate insulating film 103. The Metals used for the gate electrode 104 are Mo, W, Ti or alloys of those metals. The TFT in FIG. 1 is the driving TFT (T1), which is explained in FIG. 2; the gate electrode of the driving TFT (T1) connects with the source electrode of the selecting TFT (T2). The gate electrode of the selecting TFT (T2) is connected with the scanning line by the elastic conductive film, which is explained later.

Back to FIG. 1, the interlayer insulating film 105 is formed over the gate electrode 104 and the gate insulating film 103. The interlayer insulating film 105 is formed only in the area that covers gate insulating film 103 not in entire area of the substrate. The reason is that, since the interlayer insulating film 105 is formed by inorganic film like SiN, thus, if the interlayer insulating film 105 is formed in entire substrate, it tends to be destroyed when the display is bent. The interlayer insulating film 105 is also formed on the entire substrate by CVD, then, it is patterned by photo lithography.

After that, through holes are formed in the interlayer insulating film 105 and the gate insulating film 103, after that, the drain electrode 106 and the source electrode 107 are formed. The drain electrode 106 and the source electrode 107 are formed by e.g. Mo, W, Ti or Al alloy; those electrodes are formed only in the through holes or their neighborhood to avoid disconnection when the display device is bent. In other words, the drain electrodes and the source electrodes are formed only on the patterned interlayer insulating film 105.

The drain electrodes 106 connect with the video signal lines 20 shown in FIG. 2 by the elastic conductive films 108. The elastic conductive film 108 is a resin film like e.g. epoxy with conductive particles dispersed in it. The drain electrodes 106 can be connected with the video signal lines 20 shown in FIG. 2 by organic conductors. Since a base material of the elastic conductive films 108 is resin, it is elastic and is not destroyed even when the display device is bent.

An example of manufacturing method of the elastic conductive film 108 is as follows. Liquid material that pre-polymer for epoxy dispersed with conductive particles is coated by inkjet or spin coating on entire of the substrate. Inkjet or spin coating can form films as thin as 200 nm. Since the conductive particles must be dispersed in thin films, they are preferably materials that can be formed to fine particles like carbon nanotubes. Other materials for fine particles are graphite, metal flakes of e.g. silver.

After the material for the elastic conductive film 108 is coated on the substrate, it is prebaked, and then is patterned. Using photosensitive material as the material for the elastic conductive film, patterning can be made without using resist. After patterning, main baking is performed for the elastic conductive film. Other materials for the base materials for the elastic conductive film are e.g. acrylic or silicone. In the above example, the material for the elastic conductive film is coated on the entire substrate, then, is patterned; however, if inkjet is used, the material for the elastic conductive film is directly patterned without photolithography.

In the above example, the resin dispersed with conductive particles is used for the elastic conductive film; however, other structures can be used as far as they are elastic conductive film and is suitable for fine patterning.

The organic passivation film 109 is formed by e.g. acrylic covering the drain electrode 106, the source electrode 107 and the elastic conductive film 108. Since the organic passivation film also works as a flattening film, it is coated as thick as 2-3 μm. After that, a through hole is formed in the organic passivation film 109 to connect the source electrode 107 and the lower electrode 110, which is formed on the organic passivation film 109. Since the photo sensitive material is used for the organic passivation film, the through hole can be made without using resist.

The lower electrode 110, which is an anode, is formed on the organic passivation film. The lower electrode 110 is e.g. a laminated film of ITO (Indium Tin Oxide), Ag, and ITO. Ag works as a reflection electrode. The ITO formed under the Ag is to improve adhesion with the organic passivation film 109 and the lower electrode 110. The ITO on the Ag works as an anode for the organic EL layers. Ag can be replaced by other metal. The ITO can be replaced by other transparent conductive film like IZO (Indium Zinc Oxide).

ITO, constituting the lower electrode 110, is a hard material, and Ag is metal, thus, if the laminated film is used in the through hole, the stress becomes big; consequently, the laminated film tends to be destroyed when the display device is bent. The present invention can avoid the destruction of the conductive film in the through hole by using an elastic conductive film 108 in the through hole, thus, reliability of connection in the through hole is improved. The manufacturing method of the elastic conductive film is the same as described before.

As to superposing at the connection of the elastic conductive film 108, which is formed in the through hole, and the lower electrode 110, basically either one of the elastic conductive film 108 or the lower electrode 110 can be an upper layer. However, if the elastic conductive film 108 is formed in advance, the elastic conductive film 108 may have damage when the lower electrode 110 is patterned by etching. To avoid that possibility, it may be better to form the lower electrode 110 before the elastic conductive film 108 is formed as shown in FIG. 1.

The bank 111 is formed after the lower electrode 110 is formed. The bank 111 has roles to avoid disconnection of the organic EL layers 112 at the step of the lower electrode 110 and isolate each of the pixels. The bank 111 is formed by acrylic at a thickness about 2 μm. Formation of the bank 111 is as follows: the material for the bank 111 is coated on the entire substrate, then, the material for the bank 111 is removed from the area where light emitting region is formed. The photo sensitive material is preferable for the bank 111 for simplicity of manufacturing process.

After that the organic EL layer 112 (also called the organic layer) is formed on the lower electrode 110. The organic EL layer 112 is formed by plural layers of e.g. the hole injection layer, the hole transport layer, the light emitting layer, the electron transport layer and the electron injection layer. After that, the upper electrode 113 is formed to cover the organic EL layer 112. The upper electrode 113 constitutes a cathode, and formed by e.g. MgAg.

Conventionally, the upper electrode 113 was formed all over the substrate; in this invention, however, the upper electrode 113 is formed only on the area to cover the organic EL layer 112; the cathode voltage is supplied by the cathode line 40. The alloy of e.g. MgAg is hard, besides, the upper electrode 113 is made thin to maintain the transmittance of light; thus, the upper electrode 113 tends to be broken when the display is bent. In the present invention, the upper electrode 113 is formed only on the area that covers the organic EL layer 112, thus, the destruction of the upper electrode 113 can be avoided. By the way, to avoid corrosion of the upper electrode 113, it is also reasonable to form the upper electrode 113 only in the area where the protective layer covers.

A cathode voltage is supplied to the upper electrode 113 through the elastic conductive film 108. The manufacturing method of the elastic conductive film 108 is the same as already explained. In FIG. 1, the elastic conductive film 108 extends from the surface of the organic passivation film 109 to the upper surface of the bank 111. Using the elastic conductive film 108 can avoid disconnection even the display device is bent, and the cathode voltage can be supplied to the upper electrode 113 in stable.

Attention is paid for a connection between the upper electrode 113 and the elastic conductive film 108. MgAg of the upper electrode 113 is easily corroded by moisture. As depicted in FIG. 1, the elastic conductive film 108 is not covered by the inorganic protective film. Since the base film of the elastic conductive film 108 is resin, moisture penetrates in the elastic conductive film 108, then, corrodes the upper electrode 113.

The present invention uses the connecting electrode 114 for electrical connection between the elastic conductive film 108 and the upper electrode 113, thus, infiltration of moisture to the upper electrode 113 can be avoided. The connecting electrode 114 is a metal electrode, and can be made by Mo, W, Ti or alloys of those metals. The connecting electrode 114 is covered by the protective film, which is explained later.

Sometimes, the upper electrode 113 is formed by the transparent oxide conductive film like e.g. IZO. The oxide conductive film like IZO is endurable to moisture, thus, the elastic conductive film 108 and the upper electrode 113 can be directly connected.

In FIG. 1, the protective film is formed covering the upper electrode 113. Since characteristics of the organic EL layer 112 deteriorate by moisture, the protective film is formed to protect the organic EL layer 112. In FIG. 1, the protective film is formed by three layers of: the first inorganic protective film 115, the organic protective film 116 and the second inorganic protective film 117. The first inorganic protective film 115 is formed directly on the upper electrode 113 to directly protect the organic EL layer from moisture. The first inorganic protective film 115 is formed by e.g. SiN or SiO at a thickness of several hundred nanometers.

On the other hand, the organic protective film 116 is to protect the device mechanically, thus, the thickness is as thick as 10-15 μm. A thickness of the organic protective film 116 is double or more, preferably, triple or more of the thickness of the organic passivation film 109: more preferably, the thickness of the organic protective film 116 is 10 μm or more. The organic protective film 116 is made thick and in island shape, thus, the place where the organic EL layer 112 exists becomes hard to bend; consequently, the organic EL layer 112 is not destroyed. The organic protective film 116 is made by a transparent resin like e.g. acrylic.

The second inorganic protective film 117 is formed covering the organic protective film 116. The second inorganic protective film 117 covers the side wall of the organic protective film 116; thus, stops moisture from penetrating into the organic protective film 116. There is an area that the first inorganic protective film 115 and the second inorganic protective film 117 directly contact. The second inorganic protective film 117 is formed by e.g. SiN or SiO at a thickness of several hundred nanometers.

FIG. 2 is an equivalent circuit of the display area of the organic EL display device of the present invention. In FIG. 2, the area surrounded by the scanning lines 10, the video signal lines 20, anode lines 30 (it is also called as source lines or current supply lines) and cathode lines 40 (it is also called as common voltage supply lines). In the conventional organic EL display device, the cathode lines 40 are not necessary because the cathode (the upper electrode 113) is formed on the entire display area; in the present invention, however, the cathode lines exist because the cathode voltage (common voltage) is supplied to the individual pixels through the cathode lines 40. In FIG. 2, the cathode lines 40 extend in the same direction as the video signal line 20 and anode line 30, however, the cathode lines 40 can extend in the same direction as the scanning lines 10 according to a requirement of the layout.

In the pixel, the organic EL element (EL), which is formed by the organic EL layer, and the driving TFT (T1) to drive the organic EL element (EL) are serially connected. The TFT in FIG. 1 corresponds to the driving TFT (T1). There is a storage capacitance Cs between the gate and the source of the driving TFT (T1). A current is supplied to the organic EL element (EL) from the driving TFT (T1) according to a voltage of the storage capacitance Cs.

In FIG. 2, the gate of the selecting TFT (T2) connects with the scanning line 10; the selecting TFT (T2) becomes open or close according to ON or OFF signal of the scanning electrode 10. When the selecting TFT (T2) is ON, video signals are supplied from video signal line 20, then the charge is stored in the storage capacitance Cs according to the video signals; the driving TFT (T1) supplies a current to the organic EL element (EL) according to the voltage of the storage capacitance Cs.

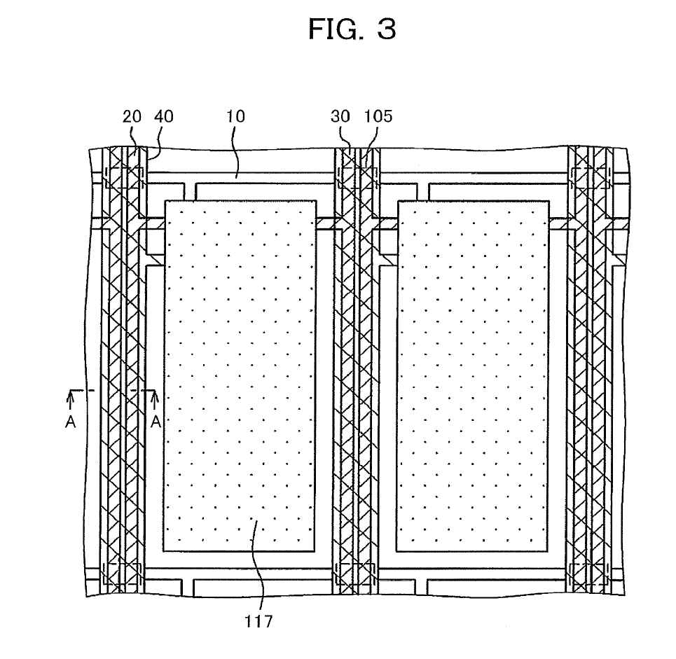

FIG. 3 is a plan view of the pixels according to the present invention. While many pixels are formed in the display area, two pixels are drawn in FIG. 3. In FIG. 3, the scanning lines 10 extend in lateral direction, while the video signal lines 20, anode lines 30 and cathode lines 40 extend in longitudinal direction. The area surrounded by the scanning lines and the video signal lines is a pixel where the organic EL layer and the TFTs are formed. It is preferable that the scanning lines 10, the video signal lines 20, anode lines 30 and cathode lines 40 are made by the elastic conductive film.

In FIG. 3, the interlayer insulating film is formed in island shape at the area where the video signal line 20 and the anode line cross the scanning line 10. This area, however, is small area, thus, a big stress is not generated even when the display device is bent. By the way, in FIG. 3, the interlayer insulating film 105 is formed in common for the video signal line 20 and the anode line 30 at the cross point with the scanning line 10; however, the interlayer insulating film 105 can be formed separately for the video signal line 20 and the anode line 30.

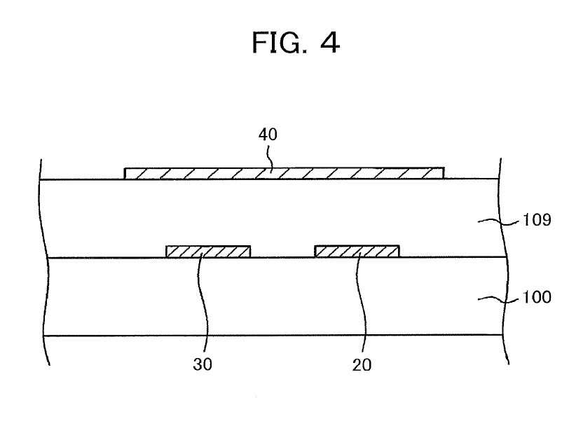

FIG. 4 is cross sectional view along the line A-A of FIG. 3. FIG. 4 shows positions of the video signal line 20, the anode line 30 and the cathode line 40. In FIG. 4, the video signal line 20 and the anode line 30 are formed in parallel on the TFT substrate 100. The organic passivation film 109 is formed covering the video signal line 20 and the anode line 30. The cathode line 40 is formed on the organic passivation film 109. In the present invention, the cathode lines 40 are necessary because the upper electrode 113 is not formed in common for the entire display area.

Wirings of the video signal lines 20, the anode lines 30 and the cathode lines 40 are examples; other wirings are possible. For example, the cathode lines 40 can extend in the same direction as the scanning lines 10 extend. In that example, an island shaped interlayer insulating film 105, formed at the area where the scanning line 10 crosses the video signal line 20 and the anode line 30, can be eliminated by forming the scanning line 10 and the cathode line 40 on the organic passivation film 109. In that example, however, the scanning line 10 is connected to the gate of the selecting TFT (T2) via a through hole formed in the organic passivation film 109.

Back to FIG. 3, only the second inorganic protective film 117 is shown in the pixel. Namely, the organic EL layer 112 and TFTs are formed under the second inorganic protective film 117. In FIG. 3, the elastic conductive film 108, diverged from the scanning line 10, extends in the pixel to connect with the gate of the selecting TFT (T2). The elastic conductive film 108, diverged from the video signal line 20, extends in the pixel to connect with the drain of the selecting TFT (T2). The elastic conductive film 108, diverged from the anode line 30, extends in the pixel to connect with the drain of the driving TFT (T1). Further, the elastic conductive film 108, diverged from the cathode line 40, extends in the pixel to connect with the upper electrode 113 on the organic EL layer 112.

As shown in FIG. 3, the area outside of the second inorganic protective film 117 is formed by resin or elastic conductive film 108; thus, the display device can bend at the area outside of the second inorganic protective 117.

As explained above, in this invention, hard elements that are formed by inorganic films of SiN or SiO, metal films or alloy films exist only at the limited areas as the overlapping area of the organic EL layer and TFTs, and areas where e.g. the scanning lines 10 and the video signal lines 20 cross to each other; other areas are formed by resin which is elastic. Therefore, when the display device is bent, the device will bend at the resin area, the bending stress is avoided at the hard area that is formed by inorganic substances. Consequently, the hard elements are not broken, thus, a flexible display device of high reliability is realized.

As shown in FIG. 1, at the state that the second inorganic insulating film 117 is formed, the surface of the organic EL display device is uneven because the organic protective film 116 or the first inorganic protective film 115 are formed only on the area where the organic EL layer 112 is formed. In the meanwhile, most of the organic EL display devices use a polarizing plate 200 to prevent the reflection. The polarizing plate 200 is adhered to the organic EL display device through the adhesive 201.

The adhesive 201 is as thick as 20 μm to 30 μm, consequently, the recesses on the surface of the organic EL display device are filled by the adhesive 201, thus, the surface of the polarizing plate 200 is flat. The polarizing plate 200 is a thickness of about 100 μm, and made by resin; thus, it doesn't hinder the organic EL display device is to be bent.

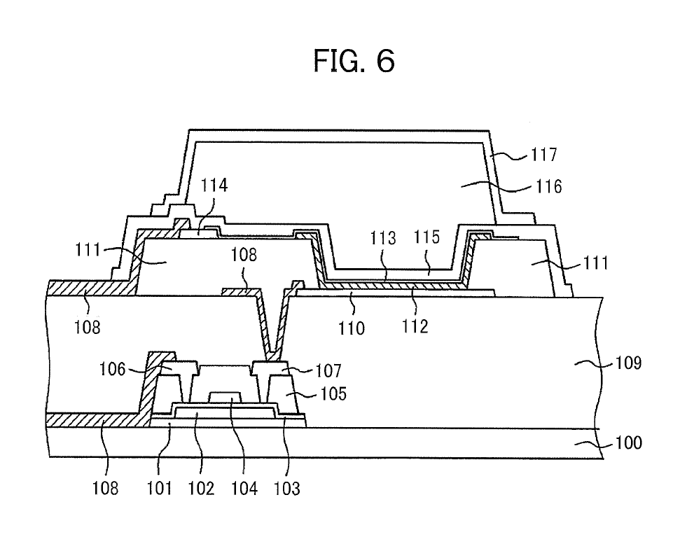

FIG. 6 is a modified structure of FIG. 1. FIG. 6 is the same as FIG. 1 except the first inorganic protective film 115 covers the side wall of the bank 111 in FIG. 6. Intrusion of moisture from the side wall of the bank 111 is suppressed by covering it by the first inorganic protective film 115. In the meantime, covering the side wall of the bank 111 by the first inorganic protective film 115 doesn't influence to the flexibility of the display device. In FIG. 6, only the first inorganic protective film 115 covers the side wall of the bank 111, however, the second inorganic protective film 117 also can cover the side wall of the bank 111.

What is claimed is:

1. An organic EL display device comprising:
a lower electrode, an upper electrode, an organic layer that is sandwiched by the lower electrode and the upper electrode, a thin film transistor connecting with the lower electrode, a first inorganic protective film covering the organic layer;
wherein a common voltage is supplied through a first elastic conductive film,
a drain electrode of the thin film transistor is connected with a power line through a second elastic conductive film.

2. The organic EL display device according to claim 1,
wherein plural pixels are formed, the lower electrode, the upper electrode and the thin film transistor are formed separately in each of the pixels,
the first inorganic protective film is formed on the upper electrode in island shape separately in each of the pixels.

3. The organic EL display device according to claim 1,
wherein an organic passivation film is formed on the thin film transistor, a source of the thin film transistor and the lower electrode are connected through a third elastic conductive film that is formed in a through hole formed in the organic passivation film.

4. The organic EL display device according to claim 2,
wherein the first elastic conductive film connects with the upper electrode through a connecting electrode that is made by metal or alloy.

5. The organic EL display device according to claim 1,
wherein the upper electrode is formed by oxide conductive film, the upper electrode connects with the first elastic conductive film directly.

6. The organic EL display device according to claim 3,
wherein an edge of the third elastic conductive film superposes on the edge of the upper electrode.

7. The organic EL display device according to claim 1,
wherein the thin film transistor is covered by the first inorganic protective film in a plan view.

8. The organic EL display device according to claim 1,
wherein an island shaped organic protective film is formed on the first inorganic protective film.

9. The organic EL display device according to claim 8,
wherein a thickness of the organic protective film is two times or more of a thickness of an organic passivation film that covers the thin film transistor.

10. The organic EL display device according to claim 8,
wherein a second inorganic protective film is formed on the organic protective film.

11. The organic EL display device according to claim 1,
wherein an island shaped undercoat film is formed between the thin film transistor and a substrate.

12. The organic EL display device according to claim 1,
wherein an island shaped gate insulating film is formed to cover a semiconductor of the thin film transistor.

13. The organic EL display device according to claim 12,
wherein an island shaped interlayer insulating film is formed to cover the semiconductor and the gate insulating film.

14. An organic EL display device comprising;
scanning lines extend in a first direction and arranged in a second direction, video signal lines and power lines extend in parallel in a second direction and arranged in a first direction, a pixel is formed in an area surrounded by the scanning line, the video signal line and the power line;
an organic layer formed between a lower electrode and an upper electrode, a first transistor that drives the organic layer, a second transistor that connects with a gate of the first transistor are formed in the pixel;
wherein the organic layer is covered by an island shaped first inorganic protective film,
a gate of the second transistor connects with the scanning line,
a drain of the second transistor connects with the video signal line,
a drain of the first transistor connects with the power line,
a source of the first transistor connects with the lower electrode,
the upper electrode connects with a common voltage supply line,
the scanning line is formed by a first elastic conductive film, the video signal line is formed by a second elastic conductive film, the power line is formed by a third elastic conductive film, the common voltage supply line is formed by a fourth elastic conductive film.

15. The organic EL display device according to claim 14,
the common voltage supply line is formed in parallel with the video signal line and the power line.

16. The display device according to claim 14,
wherein an organic passivation film is formed between the lower electrode and the first thin film transistor, the lower electrode and the source of the first thin film transistor are connected through a fifth elastic conductive film that is formed in a through hole formed in the organic passivation film.

17. The organic EL display device according to claim 14,
wherein the first thin film transistor and the second thin film transistor are covered by the first inorganic protective film in a plan view.

18. The organic EL display device according to claim 14,
wherein the first inorganic protective film doesn't cover the scanning line, the video signal line, the power line and the common voltage supply line.

19. The organic EL display device according to claim 14,
wherein the first inorganic protective film is covered by an organic protective film, the organic protective film doesn't cover the scanning line, the video signal line, the power line and the common voltage supply line.

20. The organic EL display device according to claim 14,
wherein an island shaped interlayer insulating film is formed at an area that the video signal line crosses the scanning line.
